(19) United States
(12) Patent Application Publication
(10) Pub. No.: US 2024/0395578 A1
(43) Pub. Date: Nov. 28, 2024

(54) TOOL AND PROCESSES FOR PICK-AND-PLACE ASSEMBLY

(71) Applicant: Board of Regents, The University of Texas System, Austin, TX (US)

(72) Inventors: Sidlgata V. Sreenivasan, Austin, TX (US); Paras Ajay, Austin, TX (US); Austin Anthis, Austin, TX (US)

(21) Appl. No.: 18/696,620

(22) PCT Filed: Sep. 30, 2022
(86) PCT No.: PCT/US2022/045470

§ 371 Date: Mar. 28, 2024

Related U.S. Application Data
(60) Provisional application No. 63/250,252, filed on Sep. 30, 2021.
(60) Provisional application No. 63/290,228, filed on Dec. 16, 2021.

(51) Int. Cl. H01L 21/67; B05B 17/06; B41J 3/407

(52) U.S. Cl. CPC H01L 21/67144; B05B 17/0607; B41J 3/407

(57) ABSTRACT

A system for assembling a first substrate to a second substrate. One or more deformable substrate chucks are utilized to match a topography of a bonding surface on the first substrate to a topography of a bonding surface on the second substrate, where a volatile lubricant is utilized during an alignment step.

### CROSS REFERENCE TO RELATED APPLICATIONS

This application claims priority to U.S. Provisional Patent Application Ser. No. 63/250,252 entitled “Tool and Processes for Pick-and-Place Assembly,” filed on Sep. 30, 2021, which is incorporated by reference herein in its entirety.

This application further claims priority to U.S. Provisional Patent Application Ser. No. 63/290,228 entitled “Tool and Processes for Pick-and-Place Assembly,” filed on Dec. 16, 2021, which is incorporated by reference herein in its entirety.

### TECHNICAL FIELD

The present invention relates generally to surface-mount technology component placement systems, and more particularly to a tool and process for pick-and-place assembly.

### BACKGROUND

Surface-mount technology (SMT) component placement systems, commonly called pick-and-place machines or P&Ps, are robotic machines which are used to place surface-mount devices (SMDs) onto a printed circuit board (PCB). They are used for high speed, high precision placing of a broad range of electronic components, such as capacitors, resistors, integrated circuits, etc. onto the PCBs which are in turn used in computers, consumer electronics as well as industrial, medical, automotive, military and telecommunications equipment. Similar equipment exists for through-hole components. This type of equipment is sometimes also used to package microchips using the flip chip method.

The placement equipment is part of a larger overall machine that carries out specific programmed steps to create a PCB assembly. Several sub-systems work together to pick up and correctly place the components onto the PCB. These systems normally use pneumatic suction cups, attached to a plotter-like device to allow the cup to be accurately manipulated in three dimensions. Additionally, each nozzle can be rotated independently.

Surface mount components may be placed along the front (and often back) faces of the machine. Most components are supplied on paper or plastic tape, in tape reels that are loaded onto feeders mounted to the machine. Larger integrated circuits (ICs) are sometimes supplied arranged in trays which are stacked in a compartment. More commonly ICs will be provided in tapes rather than trays or sticks. Improvements in feeder technology mean that tape format is becoming the preferred method of presenting parts on an SMT machine.

Early feeder heads were much bulkier, and as a result it was not designed to be the mobile part of the system. Rather, the PCB itself was mounted on a moving platform that aligned the areas of the board to be populated with the feeder head above.

Through the middle of the machine there is a conveyor belt, along which blank PCBs travel, and a PCB clamp in the center of the machine. The PCB is clamped, and the nozzles pick up individual components from the feeders/trays, rotate them to the correct orientation and then place them on the appropriate pads on the PCB with high precision. High-end machines can have multiple conveyors to produce multiple same or different kinds of products simultaneously.

Unfortunately, there are currently limitations in such surface-mount technology component placement systems in picking and placing components on a target device, such as a printed circuit board. For example, such surface-mount technology component placement systems are expensive and the type of components to be mounted is limited. Furthermore, the speed of such surface-mount technology component placement systems is limited.

### SUMMARY

In one embodiment of the present invention, a system for assembling a first substrate to a second substrate comprises one or more deformable substrate chucks utilized to match a topography of a bonding surface on the first substrate to a topography of a bonding surface on the second substrate, where a volatile lubricant is utilized during an alignment step.

In another embodiment of the present invention, an apparatus comprises a substrate with dies assembled on top. The apparatus further comprises a coating of a transparent material on the substrate. The apparatus additionally comprises adhesive drops between the dies and the transparent material, where the adhesive drops are inkjetted on the transparent material, where the transparent material allows light to be coupled in from a substrate periphery, and where the drops are staggered to allow the dies to be exposed to the coupled in light.

The foregoing has outlined rather generally the features and technical advantages of one or more embodiments of the present invention in order that the detailed description of the present invention that follows may be better understood. Additional features and advantages of the present invention will be described hereinafter which may form the subject of the claims of the present invention.

### BRIEF DESCRIPTION OF THE DRAWINGS

A better understanding of the present invention can be obtained when the following detailed description is considered in conjunction with the following drawings, in which:

FIG. 1 illustrates an exemplary system for pick-and-place assembly in accordance with an embodiment of the present invention;

FIG. 2 illustrates die-to-transfer-wafer alignment using alignment marks on the frontside of the die in accordance with an embodiment of the present invention;

FIG. 3 illustrates die-to-transfer-wafer alignment using alignment marks on the backside of the die in accordance with an embodiment of the present invention;

FIG. 4 illustrates die-to-transfer-wafer alignment using an angled light source and a surface-normal incoming beam into the imaging assembly in accordance with an embodiment of the present invention;

FIGS. 5A-5C illustrate front-to-back alignment of alignment marks placed on the backside of the dies in accordance with an embodiment of the present invention;

FIG. 6 illustrates an exemplary planar-motor-based transfer chucks in accordance with an embodiment of the present invention;

FIG. 7 illustrates a transfer substrate in accordance with an embodiment of the present invention;

FIGS. 8A-8B illustrate a further embodiment of the present invention of the transfer substrate; and

FIGS. 9A-9B illustrate an additional embodiment of the present invention of the transfer substrate.

### DETAILED DESCRIPTION

As stated in the Background section, unfortunately, there are currently limitations in such surface-mount technology component placement systems in picking and placing components on a target device, such as a printed circuit board. For example, such surface-mount technology component placement systems are expensive and the type of components to be mounted is limited. Furthermore, the speed of such surface-mount technology component placement systems is limited.

The principles of the present invention provide a means for picking and placing components on a target device, such as a printed circuit board, in a less expensive manner than prior surface-mount technology component placement systems. Furthermore, the tool of the present invention for pick-and-place assembly enables the type of components to be mounted to be less limiting. Additionally, the speed for such placement of the components on a target device is less limiting using the tool of the present invention.

The present application incorporates herein the following references in their entirety: U.S. Patent Application Publication No 2021/0350061 (“Nanofabrication and Design Techniques for 3D ICs and Configurable ASICs), U.S. Patent Application Publication No. 2021/0366771 (“Nanoscale-Aligned Three-Dimensional Stacked Integrated Circuit”) and U.S. Patent Application Publication No. 2021/0134640 (“Heterogeneous Integration of Components Onto Compact Devices Using Moiré Based Metrology and Vacuum Based Pick-and-Place”).

Prior to discussing the Figures, the following provides definitions for various terms used herein.

“SiP,” as used herein, refers to “system-in-package” where separately manufactured die are integrated into a higher-level assembly. A SiP is formed of separately manufactured dice that have been physically and/or functionally integrated so as to create a system larger than each individual die. It is used interchangeably with the term Multi-Chip Module (MCM), 2.5D IC and 3D IC herein.

“Field,” as used herein, refers to individual die, or a small cluster of die collocated in the SiP.

“SPP,” as used herein, refers to SiP pitch on product-substrate (SPP) including SPPₓ and SPP_{y}.

“Transfer chuck (TC),” as used herein, refers to a system that is used to transfer fields and/or dies from one substrate to another while maintaining thermo-mechanical stability of said fields and/or dies.

“Variable pitch mechanism (VPM),” as used herein, refers to a sub-system of the transfer chuck, which can be used to change the pitch of the dies picked up by the transfer chuck prior to placement onto a transfer/product/intermediate substrate.

“Adaptive chucking module (ACM),” as used herein, refers to a sub-system of the transfer chuck, which can be used to securely hold dies of non-arbitrary and/or arbitrary lateral dimension (within pre-defined maximum and minimum lateral dimensions), in a thermo-mechanically stable manner. Furthermore, ACM and its auxiliary systems (such as the ACM receptacle), as well as one or more dies that are being held by an ACM, are referred to, interchangeably, as the ACM system, ACM assembly, ACM receptacle, and cross-point puck.

“Alignment,” is used herein interchangeably with the terms “overlay” and “placement.”

“Metrology microscope assembly,” as used herein, refers to a sub-system for measuring the alignment of dies with respect to a reference. This could consist of the metrology optics, imagers, and electronics.

“Mini transfer chuck (Mini-TC),” as used herein, refers to a sub-system of the transfer chuck, which can be used to securely hold dies of non-arbitrary and/or arbitrary lateral dimension (within pre-defined maximum and minimum lateral dimensions), in a thermo-mechanically stable manner. The term mini-TC is used interchangeably with the term adaptive chucking module (ACM) herein. Also, the mini-TC and its auxiliary systems (such as the mini-TC receptacle) as well as one or more dies that are being held by the mini-TC, are referred to herein, interchangeably, as the mini-TC system, mini-TC assembly, mini-TC receptacle, and the cross-point puck.

“Actuation units,” as used herein, are used to actuate one or more dies, along one or more of the X, Y, Z, θ_{X}, θ_{Y}, and θ_{Z} axes. These could also to be used to create deformation in the one or more dies. In the description of the following Figures, the actuation units are also referred to as short-stroke actuators and short-stroke stages.

“Wafer,” as used herein, is used interchangeably with the word substrate.

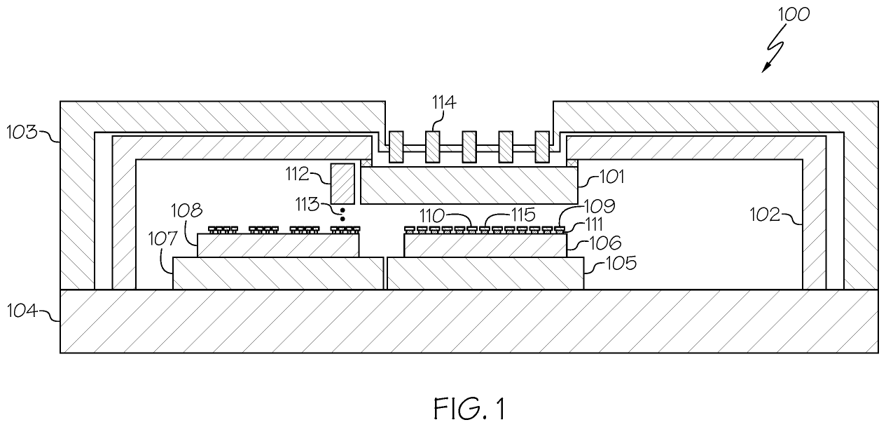

Referring now to FIG. 1, FIG. 1 illustrates an exemplary system 100 for pick-and-place assembly in accordance with an embodiment of the present invention.

As shown in FIG. 1, such a system 100 includes a transfer chuck (TC) 101 along with a transfer chuck (TC) frame 102. Furthermore, system 100 includes a stable metrology frame 103, where both frames 102, 103 are mounted on XY motion stage 104.

Furthermore, as shown in FIG. 1, source substrate chuck 105, which holds a source substrate 106, as well as transfer substrate chuck 107, which holds a transfer substrate 108, are placed on XY motion stage 104.

Additionally, as shown in FIG. 1, source substrate 106 includes good dies 109, bad dies 110 as well as die release adhesive 111. Furthermore, as shown in FIG. 1, system 100 may include an optional inkjet 112 for dispensing of adhesive 113, such as on transfer substrate 108.

Furthermore, system 100 may include optional alignment microscopes 114.

A further discussion regarding system 100 is provided below.

As shown in FIG. 1, system 100 includes transfer chuck (TC) 101 for picking up one or more dies 115 from source substrate 106 and placing them onto transfer substrate 108. In one embodiment, TC 101 contains a variable pitch mechanism (VPM) for changing the pitch of dies 115 picked up from source substrate 106 prior to placing them onto transfer substrate 108 (or any other substrate that the dies need to be placed on). A set of alignment microscopes could be used to measure the alignment/placement precision of dies 115 during one or more of the die pickup and die placement steps. In one embodiment, source substrate 106 is held onto a thermo-mechanically stable substrate chuck 105. In one embodiment, substrate chuck 105 optionally has embedded addressable light sources to expose the die adhesive, such as adhesive 113. In one embodiment, adhesive 113 is a light-switchable adhesive. In one embodiment, the light sources are composed of addressable arrays of UV light sources at 365 nm wavelength and visible light sources at 520 nm wavelength. In one embodiment, TC 101 contains an array of short-stroke stages attached to the VPM, corresponding to the group of dies 115 to be picked up, to displace dies 115 locally and/or precisely in one or more of the X, Y, Z, θ_{X}, θ_{Y}, and θ_{Z} axes. In one embodiment, TC 101 attaches to the group of dies 115 to be picked-and-placed using a group of adaptive transfer chucks (ACMs). In one embodiment, TC 101 contains an array of cross-point pucks (CPPs), corresponding to the group of dies 115 to be picked-and-placed, where each cross-point puck interfaces with the VPM as well as the short-stroke stage and the ACM. The cross-point pucks could also act as local nodes for cable routing and management as well as for thermal management.

In one embodiment, transfer chuck (TC) 101 is used for picking up one or more dies 115 from a source substrate 106 and placing them onto a product substrate. In one embodiment, TC 101 is used to permanently bond the picked dies 115 onto the product substrate. Examples of such bonding include hybrid bonding, fusion bonding, thermo-compression bonding, eutectic bonding, solder bump bonding, micro-bump bonding, wire bonding, etc. The system for pick-and-place assembly, which contains TC 101, could contain additional sub-systems to support the bonding techniques. In one embodiment, the system for pick-place assembly could contain heaters, high-pressure-creating subs-systems, solder dispense sub-systems, solder reflow sub-systems, plasma cleaning sub-systems, and/or plasma activation subs-systems.

In one embodiment, a high-throughput pick-and-place system (for instance, a chip shooter) is utilized to pick-and-place dies from source substrate 106 to transfer substrate 108. In one embodiment, the throughput of the chip shooter is optimized to match the throughput of other components in series in the pick-and-place assembly line (for instance, adhesive dispense stations, precise alignment modules, etc.).

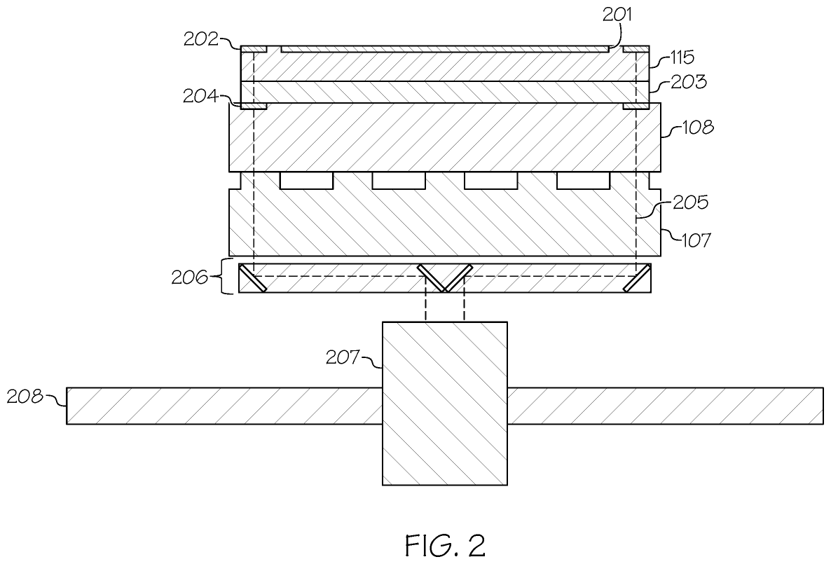

FIG. 2 illustrates die-to-transfer-wafer alignment using alignment marks on the frontside of die 115 in accordance with an embodiment of the present invention.

Referring to FIG. 2, FIG. 2 illustrates a portion of transfer substrate chuck 107 and a portion of transfer substrate 108. Furthermore, FIG. 2 illustrates circuit elements 201 and top-side peripheral alignment marks 202 on die 115 which is held by transfer substrate 108 via fluid 203 (e.g., liquified adhesive). In one embodiment, fluid 203 between die 115 and transfer substrate 108 (or any other substrate on which die alignment is being performed) is a light-sensitive adhesive.

FIG. 2 further illustrates an exemplary and optional complementary mark 204 on transfer substrate 108 for moiré metrology. Furthermore, FIG. 2 illustrates an exemplary light path 205, where, for example, infrared (IR) light, is used in the alignment metrology. Additionally, FIG. 2 illustrates an optional mirror assembly 206 to sense multiple marks using a single imager assembly.

Furthermore, FIG. 2 illustrates an exemplary alignment optics and imaging assembly 207 which may be placed over an optional VPM 208.

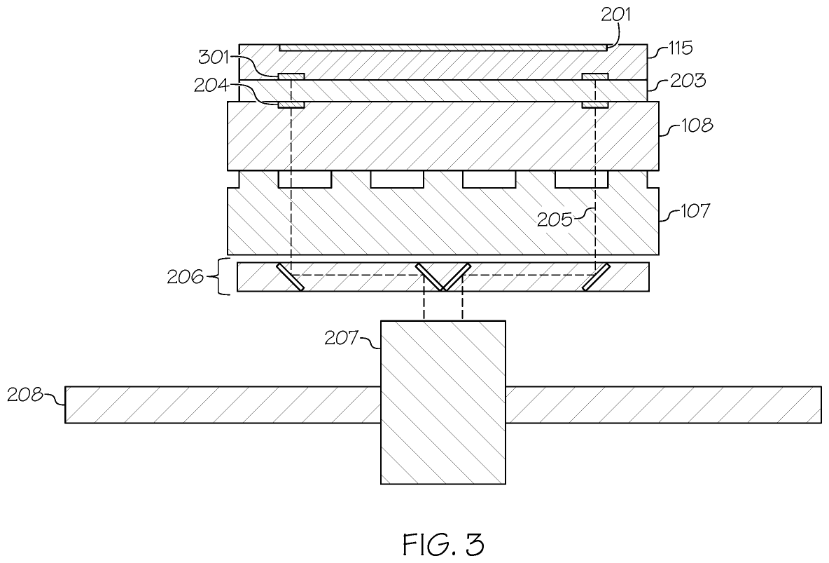

Referring now to FIG. 3, FIG. 3 illustrates die-to-transfer-wafer alignment using alignment marks on the backside of die 115 in accordance with an embodiment of the present invention.

As shown in FIG. 3, bottom-side alignment marks 301 are now utilized for die-to-transfer-wafer alignment. Furthermore, FIG. 3 illustrates exemplary and optional complementary marks 204 on transfer substrate 108 for moiré metrology. It is noted that such marks 204 in FIG. 3 are located in a different location than marks 204 in FIG. 2 since such marks 204 are complementary to bottom-side alignment marks 301 (see FIG. 3).

Additionally, FIG. 3 illustrates an exemplary light path 205, where, for example, visible or infrared (IR) light, is used in the alignment metrology.

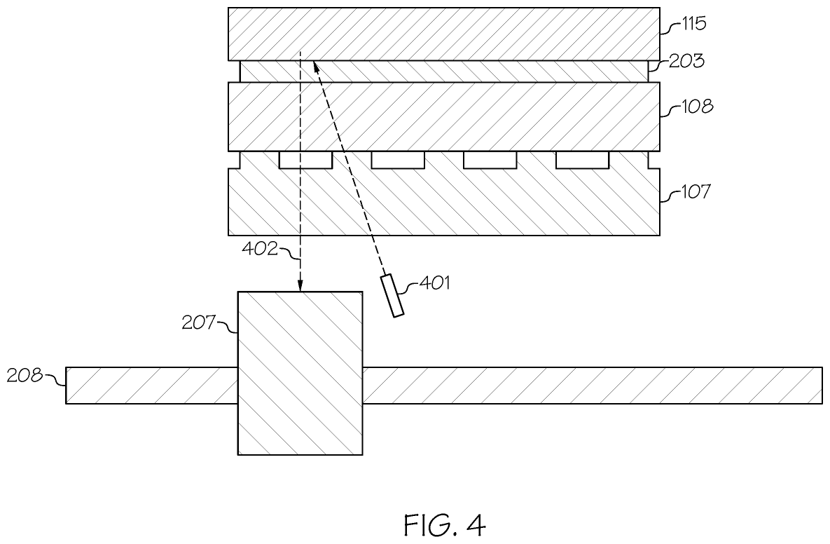

FIG. 4 illustrates die-to-transfer-wafer alignment using an angled light source and a surface-normal incoming beam into the imaging assembly in accordance with an embodiment of the present invention.

As shown in FIG. 4, FIG. 4 illustrates an exemplary angled incident light 401 towards an alignment mark on die 115. It is noted that die 115 and the alignment marks are not shown in detail in FIG. 4. FIG. 4 further illustrates an exemplary incoming light 402 towards imaging assembly 207 (with alignment information) that is orthogonal to the plane of die 115.

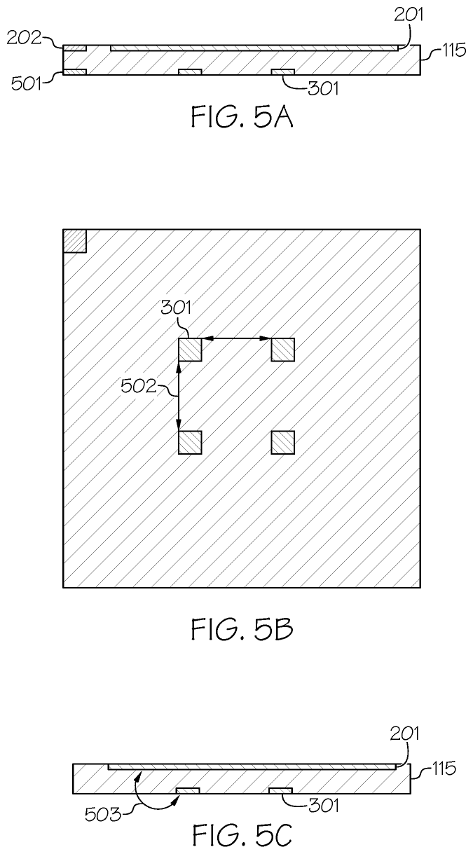

Referring now to FIGS. 5A-5C, FIGS. 5A-5C illustrate front-to-back alignment of alignment marks placed on the backside of dies 115 in accordance with an embodiment of the present invention.

Referring to FIG. 5A, FIG. 5A illustrates die 115 prior to slicing, which includes top-side peripheral alignment marks 202, bottom-side peripheral alignment marks 501, circuit elements 201 and the bottom-side main alignment marks 301.

In one embodiment, the X/Y distance 502 between the bottom-side main alignment marks 301 is smaller than the smallest X and Y lateral dimension for all dies 115 on the transfer substrate/intermediate substrate/product substrate (e.g., transfer substrate 108) as shown in FIG. 5B.

In one embodiment, the position of the top and bottom peripheral marks 202, 501 with respect to circuit elements 201 and main alignment marks 301 is known by design. Thus, the alignment between circuit elements 201 and bottom-side main alignment marks 301 may be obtained by measuring the alignment between peripheral marks 202, 501 prior to dicing. In one embodiment, peripheral marks 202, 501 may be diced out post-measurement.

Referring to FIG. 5C, FIG. 5C illustrates die 115 post-dicing where the relative positions 503 between circuit elements 201 and bottom-side main alignment marks 301 are known.

Referring to FIGS. 2-4 and 5A-5C, in one embodiment, transfer substrate 108 contains a group of alignment marks (e.g., alignment marks 204). In one embodiment, the group of alignment marks are on a rectilinear grid or groups of rectilinear grids. In one embodiment, the alignment marks (e.g., alignment marks 204) are suitable for moiré-based alignment metrology, on-axis imaging-based metrology or off-axis imaging-based metrology. In one embodiment, transfer substrate 108 is made of a thermo-mechanically stable substrate. In one embodiment, transfer substrate 108 is made of silicon, silicon carbide, silicon oxide, sapphire, polymers, polymer coatings, metals, metal coatings, etc. and any combination thereof. In one embodiment, transfer substrate 108 is maintained in a thermo-mechanically stable state using thermal actuators for instance, such that the relative displacement of the group of alignment marks on transfer substrate 108 is minimized. In one embodiment, the alignment marks (e.g., alignment marks 204) are made on the frontside and/or the backside of transfer substrate 108. The alignment marks (e.g., alignment marks 204) are made on transfer substrate 108 (using etching, for instance) or a coating on transfer substrate 108 using patterning techniques, such as nano-imprint lithography, photolithography, etc.

In one embodiment, dies 115 (that are intended to be placed on transfer substrate 108) contain one or more alignment marks (e.g., alignment marks 202, 501). In one embodiment, the alignment marks (e.g., alignment marks 202, 501) are suitable for moiré-based alignment metrology, on-axis imaging-based metrology, off-axis imaging-based metrology, etc. The alignment marks (e.g., alignment marks 202, 501) are made on the frontside and/or the backside of die 115. The alignment marks (e.g., alignment marks 202, 501) are made on die 115 itself (using etching, for instance) or a coating on die 115 using patterning techniques, such as nano-imprint lithography, photolithography, etc.

In one embodiment, the alignment marks on the backside of dies 115, such as alignment marks 301, are aligned with respect to corresponding alignment marks on transfer substrate 108, where the location of the die backside alignment marks is known with respect to the die frontside. This alignment could be conducted in-parallel with die actuation during die placement onto transfer substrate 108. In one embodiment, the alignment is performed using a moiré-based alignment technique. In one embodiment, alignment optics and imaging assembly 207 is placed on the opposite side of transfer substrate chuck 107 as transfer substrate 108. In one embodiment, transfer substrate chuck 107 is constructed in part, or in full, using materials that are transparent to the wavelength(s) of light used in alignment metrology. In one embodiment, transfer substrate chuck 107 is constructed using sapphire, transparent silicon carbide, silicon, silicon carbide, fused silica, polymer coatings, polymers, metal coatings, metals, etc. or any combination thereof. The pins of transfer substrate chuck 107, and the alignment marks on dies 115 could be positioned in such a manner that for any arbitrary die 115, at most one chuck pin overlaps with an alignment mark on die 115 (for instance, by placing the die alignment marks on a rectilinear grid and placing the chuck pins in a non-rectilinear grid). In one embodiment, the gap between the backside of transfer substrate 108 and the frontside of transfer substrate chuck 107 is filled using a fluid that is index matched to the chuck pins. Examples of such fluid include isopropanol, water, etc.

In one embodiment, the alignment marks (e.g., alignment marks 202) on the frontside of dies 115 are aligned with respect to corresponding alignment marks (e.g., alignment marks 204) on transfer substrate 108. In one embodiment, such an alignment is conducted in-parallel with die actuation during die placement onto transfer substrate 108. In one embodiment, the alignment is performed using a moiré-based alignment technique or an infrared (IR) light-based moiré alignment technique. In one embodiment, alignment optics and imaging assembly 207 is placed on the opposite side of transfer substrate chuck 107 as transfer substrate 108. In one embodiment, transfer substrate chuck 107 is constructed in part, or in full, using materials that are transparent to the wavelength(s) of light used in alignment metrology. In one embodiment, transfer substrate chuck 107 is constructed using sapphire, transparent silicon carbide, silicon, silicon carbide, fused silica, polymer coatings, polymers, metal coatings, metals, etc. In one embodiment, the pins of transfer substrate chuck 107 and the alignment marks on dies 115 are positioned in such a manner that for any arbitrary die 115, at most one chuck pin overlaps with an alignment mark on die 115 (for instance, by placing the die alignment marks on a rectilinear grid and placing the chuck pins in a non-rectilinear grid). In one embodiment, the gap between the backside of transfer substrate 108 and the frontside of transfer substrate chuck 107 is filled using a fluid that is index matched to the chuck pins. Examples of such a fluid include isopropanol, water, etc.

In one embodiment, alignment optics and imaging assembly 207 corresponding to each die 115 is attached to a variable pitch mechanism (VPM) (e.g., VPM 208) that adjusts the distance between the alignment optics and imaging assemblies such that this distance is matched with the distance between dies 115 being placed on transfer substrate 108. In one embodiment, the light source for moiré alignment metrology is at an angle (e.g., incident light 401), such that the diffracted light with the alignment signal comes out normal to die 115 and/or the plane of transfer substrate 108. In one embodiment, one or more mirror assemblies 206 are utilized to collect light from one or more corners of one or more dies 115 and integrate the alignment signals into one or more output signals. In one embodiment, one or more mirror assemblies 206 are utilized to distribute light to one or more corners of one or more dies 115.

In one embodiment, alignment metrology of dies 115 with respect to transfer substrate 108 (or any other substrate onto which dies 115 are being placed, for instance, the product substrate) could be performed using absolute position measurement techniques (for instance, imaging-based metrology methods), and relative alignment measurement techniques (for instance, moiré-based alignment methods).

The following discusses an embodiment regarding overlay control in substrate-to-substrate hybrid bonding.

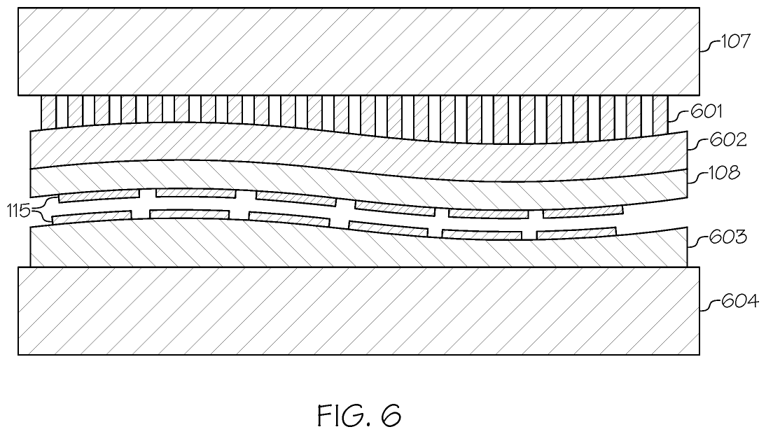

In one embodiment, during the substrate-to-substrate hybrid bonding step, a deformable transfer substrate chuck is utilized to match the topography of the bonding surface of the dies on the product substrate to the bonding surface of the dies on the transfer/intermediate substrates. In one embodiment, the deformable chuck contains an array of embedded piezo actuators to actuate a deformable chucking plate which could attach to the transfer substrate, and to which the transfer substrate could conform to. In one embodiment, the deformable chucking plate contains appropriately sized pins to reduce the issue of backside particles. In one embodiment, the topography of the bonding surface of the dies on the product substrate is measured using one or more of the following: air gages, laser-based topography measurement and tip-based topography measurement techniques. In one embodiment, the transfer substrate chuck also contains in-plane global actuators, as well as local actuators, for overlay correction (which could include thermal actuators). In one embodiment, in-situ overlay/alignment sensing is performed using moiré-based techniques (such as IR wavelength-based moiré metrology). In a further embodiment, lubrication is provided during the alignment step, prior to hybrid bonding, using a volatile lubricant. In one embodiment, the lubricant is dispensed prior to bonding, onto the product substrate, using an inkjet-based method. An exemplary planar-motor-based TCs is depicted in FIG. 6.

Referring now to FIG. 6, FIG. 6 illustrates an exemplary planar-motor-based TCs in accordance with an embodiment of the present invention.

As shown in FIG. 6, an array of piezo actuators 601 is utilized to actuate a deformable chucking plate 602 which is attached to transfer substrate 108. As also shown in FIG. 6, the topography of deformable chucking plate 602 matches the topography of transfer substrate 108.

Furthermore, as shown in FIG. 6, deformable chucking plate 602 is utilized to match the topography of the bonding surface of dies 115 on product substrate 603 held by product substrate chuck 604 to the bonding surface of the dies 115 on transfer substrate 108.

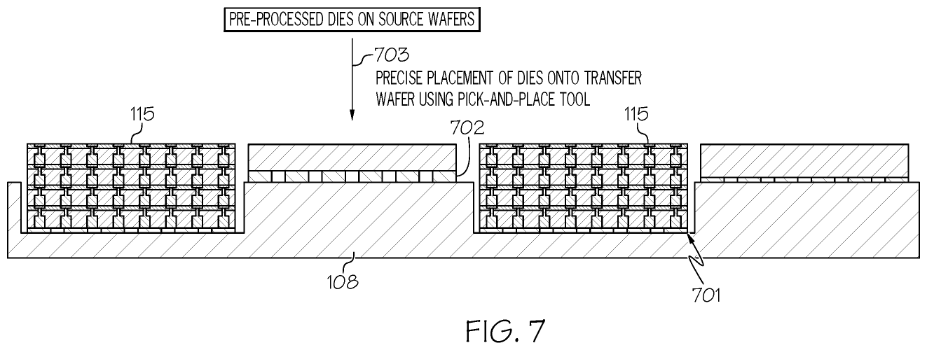

Referring now to FIG. 7, FIG. 7 illustrates a transfer substrate (“transfer wafer”) 108 in accordance with an embodiment of the present invention.

As shown in FIG. 7, transfer wafer 108 may include recesses 701 in order to line up dies 115 at the top plane. Furthermore, the volume of adhesive 702 can be precisely controlled for die height adjustment. Furthermore, FIG. 7 illustrates, as discussed herein, the precise placement of dies 115 from source wafers, such as source substrate 106, onto transfer wafer 108 using a pick-and-place tool (see element 703).

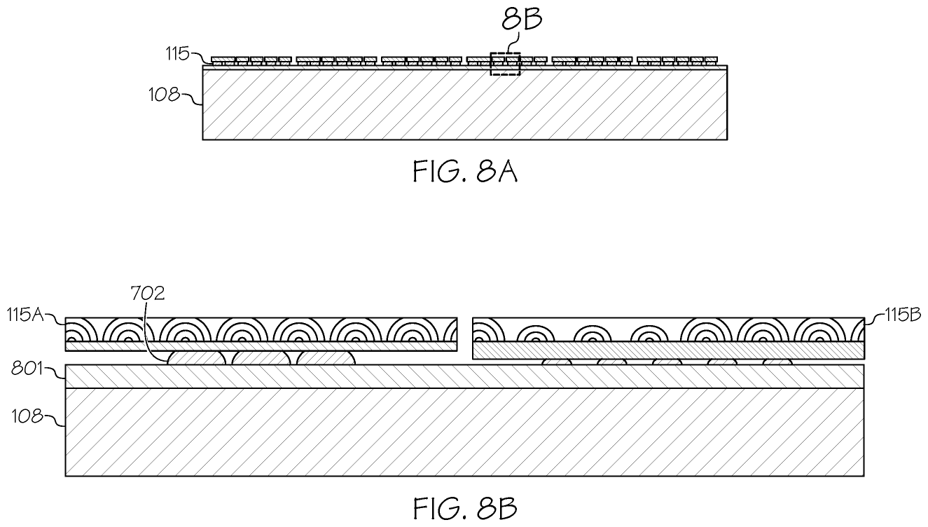

Referring now to FIGS. 8A-8B, FIGS. 8A-8B illustrate a further embodiment of the present invention of the transfer substrate.

As shown in FIG. 8A, dies 115 of varying lengths have been transferred to transfer substrate 108. A cross-sectional view of transfer substrate 108 illustrating dies 115 of varying lengths is shown in FIG. 8B.

Referring to FIG. 8B, in order to compensate dies 115, such as dies 115A, 115B, of varying lengths, the drop volume of adhesive 702 (e.g., inkjetted UV-curable adhesive) is tuned so as to compensate for die-height variation. In one embodiment, drops of adhesive 702 are dispensed away form the edge of die 115. In such an embodiment, die cantilevering is permitted near the edge during hybrid bonding. Due to the small thickness of die 115, the resulting overlay error is minimal.

Furthermore, as shown in FIG. 8B, a UV (ultraviolet) waveguide layer 801 is utilized for curing of adhesive 702.

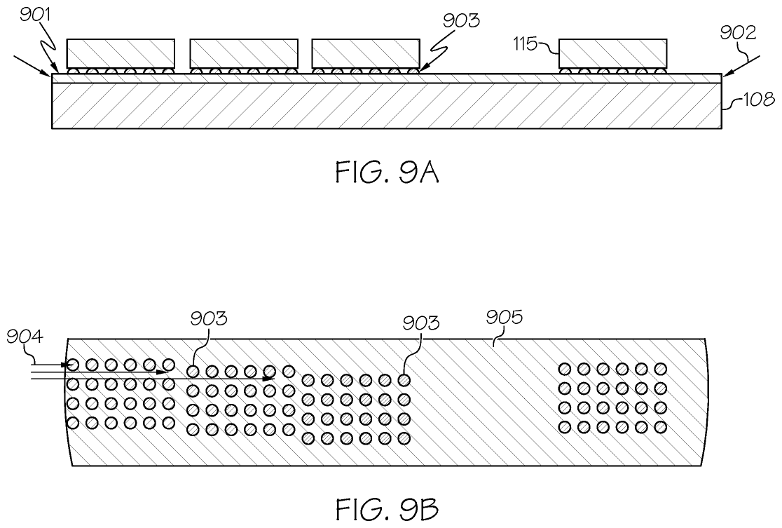

Referring now to FIGS. 9A-9B, FIGS. 9A-9B illustrate an additional embodiment of the present invention of the transfer substrate.

As shown in FIG. 9A, a layer of transparent material 901 (e.g., chemical vapor deposition (CVD) oxide, alumina, etc.) resides on transfer wafer 108. In one embodiment, the thickness of transparent material 901 is between 3-10 μm.

As also shown in FIG. 9A, UV light 902 is coupled in from the periphery of transfer wafer 108 (e.g., using diffractive gratings). Furthermore, as shown in FIG. 9A, inkjet drops 903 are index matched to the layer of transparent material 901.

FIG. 9B illustrates a cross-section of the layer of transparent material 901 illustrating the placement of inkjet drops 903. As shown in FIG. 9B, inkjet drops 903 are staggered to allow each die 115, even those that are near the center of wafer 108, to be exposed to the UV light 902 sent in from the periphery (see element 904). It is noted that individual drops 903 within a die 115 could be staggered as well (not shown in FIG. 9B).

Furthermore, as shown in FIG. 9B, there may be an empty space 905 on wafer 108 which could be used for future assembly.

Referring to FIGS. 6-7, 8A-8B and 9A-9B, in one embodiment, dies 115 could be attached to one or more of the source/transfer/intermediate/product substrate using a switchable phase-change adhesive (e.g., adhesive 702). In one embodiment, one or more of light-based, thermal, and/or electrical de-wetting methods are used to reduce die pickup force from the source/intermediate substrates (e.g., source substrate 106). In one embodiment, the transfer substrate, such as transfer substrate 108, is composed of one or more of the following: metal, alloys, glass, display glass, sapphire, sapphire-on-silicon, silicon, silicon carbide, and silicon nitride. In one embodiment, the transfer substrate, such as transfer substrate 108, has recesses 701 of varying heights to accommodate dies 115 of varying heights. In one embodiment, recesses 701 of varying heights are machined prior to pick-and-place assembly (for instance, using micro-machining techniques). The transfer substrate, such as transfer substrate 108, may now be able to accommodate dies 115 of varying height, where the height variation is present by design.

As a result of the foregoing, the principles of the present invention provide a means for picking and placing components on a target device, such as a printed circuit board, in a less expensive manner than prior surface-mount technology component placement systems. Furthermore, the tool of the present invention for pick-and-place assembly enables the type of components to be mounted to be less limiting. Additionally, the speed for such placement of the components on a target device is less limiting using the tool of the present invention.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A system for assembling a first substrate to a second substrate, comprising:
one or more deformable substrate chucks utilized to match a topography of a bonding surface on said first substrate to a topography of a bonding surface on said second substrate, wherein a volatile lubricant is utilized during an alignment step.

2. The system as recited in claim 1, wherein said first substrate is bonded to said second substrate using hybrid bonding.

3. The system as recited in claim 1, wherein at least one of said one or more deformable substrate chucks contains an array of piezo actuators.

4. The system as recited in claim 1, wherein said topography of said bonding surface on said first and second substrates is measured using one or more of the following: an air gage, a laser-based topography measurement technique and a tip-based topography measurement technique.

5. The system as recited in claim 1, wherein at least one of said one or more deformable substrate chucks contains actuators for overlay correction.

6. The system as recited in claim 5, wherein said actuators comprise thermal actuators.

7. The system as recited in claim 5, wherein in-situ overlay metrology is performed using moiré-based techniques.

8. The system as recited in claim 7, wherein said in-situ overlay metrology utilizes IR wavelengths.

9. The system as recited in claim 1, wherein said lubricant is dispensed using an inkjet-based method.

10. An apparatus, comprising:
a substrate with dies assembled on top;
a coating of a transparent material on said substrate; and
adhesive drops between said dies and said transparent material, wherein said adhesive drops are inkjetted on said transparent material;
wherein said transparent material allows light to be coupled in from a substrate periphery, and wherein said drops are staggered to allow said dies to be exposed to said coupled in light.
